(19) United States
(12) Patent Application Publication
(10) Pub. No.: US 2025/0246838 A1
(43) Pub. Date: Jul. 31, 2025

(54) ELECTRONIC CONTROL UNIT WITH A BACK-UP POWER SUPPLY

(71) Applicant: VEONEER SWEDEN SAFETY SYSTEMS AB, Stockholm (SE)

(72) Inventors: Anatolie SAVIN, Iasi (RO); Adrian CACU, Iasi (RO)

(73) Assignee: VEONEER SWEDEN SAFETY SYSTEMS AB, Stockholm (SE)

(21) Appl. No.: 19/119,567

(22) PCT Filed: Jul. 24, 2023
(86) PCT No.: PCT/EP2023/070444

§ 371 Date: Apr. 9, 2025

(30) Foreign Application Priority Data
Aug. 5, 2022 (EP) 22188929.8

(51) Int. Cl. H01R 13/24; H01R 12/70; H01R 13/66; H05K 5/00

(52) U.S. Cl. CPC H01R 13/2435; H01R 12/7076; H01R 12/7088; H01R 13/6625; H05K 5/0069; H01R 2201/26

(57) ABSTRACT

The invention relates to an electronic control unit. A back-up power supply for the electronic control unit is defined by at least two capacitors. The at least two capacitors are accommodated in a housing part of the electronic control unit. A first insulation displacement connector is positioned in a first tower, and a second insulation displacement connector is positioned in a second tower. A first electric line of each capacitor is connected to the first insulation displacement connector, and a second electric line is connected to the second insulation displacement connector.

### FIELD OF THE INVENTION

The invention relates to an electronic control unit with a back-up power supply. The electronic control unit is defined by at least two capacitors, wherein the at least two capacitors are accommodated in a housing part of the electronic control unit. Each capacitor has a first electric line and a second electric line.

### DESCRIPTION OF THE BACKGROUND ART

US 2021/012972 A1 relates to a mounting structure for mounting an electrolytic capacitor on a printed circuit board (PCB) of an airbag electronic control unit (ECU) including a cap for receiving a lead end of the capacitor. The cap includes openings for receiving electrical leads of the capacitor. The cap supports electrical connectors which electrically contact the electrical leads when a lead end of the capacitor is installed in the cap. The electrical connectors include portions for interfacing with the PCB to electrically connect the electrical connectors to the PCB.

US 2003/199195 A1 discloses an electronic control unit (control box) having the features of the preamble of claim 1.

US 2018/242460 A1 discloses a connector module used in a controller, wherein the electrolytic capacitors share a common receiving element.

US 2011/244712 A1 discloses an electrical appliance including a housing having a holding chamber and an insert slot, an insulation displacement connector (IDC), and an electrical component such as a battery inserted into the holding chamber. The component has an electric connector extending through the holding chamber into the insert slot. Upon insertion of the IDC into the insert slot, the IDC contacts the electric connector of the component and contacts a printed circuit board (PCB) mounted to the housing whereby the electrical component and the PCB are electrically connected via the electric connector of the component and the IDC.

U.S. Pat. No. 6,163,460 A discloses an arrangement of electronic components in a housing including the housing, at least one circuit board arranged in the housing with electronic components of a first type (such as SMDs) mounted thereon, at least one electronic component of a second type (such as a non-SMD coil or capacitor) that is not arranged on the circuit board but rather is mounted on a mounting surface in the housing, and an electrical connection established between the second electronic component and the circuit board. The electrical connection may be established by a connector member having two connecting shanks connected to the wires of the second component and two mounting shanks that are press-fit into contact holes of the circuit board. Alternatively, the electrical connection may be established by respective contact clips electrically and mechanically clamped onto the wires of the second component, whereby the contact clips have contact pins that plug into contact holes in the circuit board.

As known, an electrical control unit (ECU) is an embedded electronic device. A typical ECU consists of a printed circuit board (PCB), a housing part with a bottom, a cover and, in some cases, a back-up power unit. It is necessary to ensure that the ECU is supplied with power even in cases where the main power unit has a malfunction. For this reason, the back-up power unit is provided, which is often a relatively heavy capacitor. In the case of plastic housings, the fixation of the back-up power unit is realized via a mounting structure, also called a “cradle”, with a plastic snap-fit solution. The mounting structure is an integral part of the bottom of a plastic housing part.

Airbags ECUs require energy reserve capacitors to operate and send deployment signals to pyrotechnic devices embedded in airbag cushions or seatbelt mechanisms in the event that the power line between the ECU and the vehicle battery is interrupted as a result of a collision.

Some airbag ECUs use a single capacitor that is shorter or longer depending on the amount of energy required. If the required energy is greater than what one capacitor can provide, two or more capacitors are used. As safety regulations become more stringent, the number of airbags increases, and so does the amount of required energy reserve. The point is that two or more capacitors will be widely used in airbag ECUs in the near future.

### SUMMARY OF THE INVENTION

It is an object of the present invention to provide an electronic control unit with an increased back-up power ability, a compact design and a reduction of costs and material.

The above object is achieved by an electronic control unit according to the features of claim 1.

In an embodiment, an electronic control unit comprises a back-up power supply defined by at least two capacitors, wherein the at least two capacitors are accommodated in a housing part of the electronic control unit, and each capacitor has a first electric line and a second electric line. According to an embodiment of the present invention, the electronic control unit has a first insulation displacement connector positioned in a first tower. Additionally, the electronic control unit has a second insulation displacement connector positioned in a second tower. The first electric line of each capacitor is connected to the first insulation displacement connector, and the second electric line is connected to the second insulation displacement connector.

The advantage of the embodiment is that the number of required insulation displacement connectors is reduced, which not only saves space on the housing part of the electronic control unit, but also saves production costs and material. Moreover, the arrangement of the capacitors on the housing part can be made in a more compact manner.

The capacitor package becomes more compact because some insulation displacement connectors and the corresponding towers for insulation displacement connectors are eliminated. Since the number of towers and the number of capacitors determine the module size, this means the overall dimension of the electronic control unit will decrease when using the same insulation displacement connectors and towers for multiple capacitors.

The first insulation displacement connector and the second insulation displacement connector each have a plurality of slots. The number of slots corresponds to the number of capacitors forming the back-up power supply. The first insulation displacement connector and the second insulation displacement connector may be inserted into a slide of the first tower and the second tower, respectively. In an embodiment, a first support and a second support are provided on both sides of the slide of the first tower and the second tower. The first support and the second support are used as a support for the first and second electric lines from the number of capacitors, respectively.

In an embodiment, a plurality of grooves are formed in the first support and in the second support of the first tower for supporting the first electric line from the capacitors. A plurality of grooves is formed in the first support and in the second support of the second tower for supporting the second electric line from the capacitors.

The inserted first insulation displacement connector electrically contacts the first electric lines from each capacitor. The inserted second insulation displacement connector electrically contacts the second electric lines from each capacitor.

The grooves have the advantage of orienting, aligning and supporting the first electric lines and the second electric lines so that they are oriented and aligned with respect to the slots of the first and second insulation displacement connectors when the same are inserted into the slots.

The capacitors are connected in parallel when the first electric lines of each capacitor are connected through the first insulation displacement connector and when the second electric lines of each capacitor are connected through the second insulation displacement connector. The voltage applied to all capacitors connected in parallel is the same. The capacitors connected in parallel have a “common voltage” supply.

According to one embodiment, the first insulation displacement connector and the second insulation displacement connector each have a plate-shaped form which fits into the slide of the first tower. The inserted first insulation displacement connector and the inserted second insulation displacement connector contact the first electric lines and the second electric lines from the capacitors, respectively. The electric contact is carried out with the slots in the plate-shaped form of the first insulation displacement connector and the inserted second insulation displacement connector.

Each of the slots of the first insulation displacement connector and the second insulation displacement connector is delimited by a pair of fingers.

According to one embodiment of the first and second insulation displacement connector, both have three fingers, which may look like a fork with three fingers, and two slots. As mentioned above, the slots can receive the first electric line (lead) or the second electric line (lead). The first electric line and the second electric line are parallel. In a further embodiment, the first and second insulation displacement connector each have four fingers and three slots.

According to a further embodiment of the invention, a third support is provided. The third support is separate from the first support of the first tower and the second tower, respectively. In an embodiment, the first support, the second support and the third support of the first tower have at least one groove formed to support the first electric lines from the capacitors. Additionally, at least one groove is formed in the first support, the second support and the third support of the second tower for supporting the second electric lines from the capacitors.

Accordingly, in an embodiment, the first insulation displacement connector and the second insulation displacement connector are composed of a first plate-shaped form and a second plate-shaped form. Both are parallel to each other and electrically and mechanically connected with a bracket. In case the electronic control unit is equipped with two capacitors, the first plate-shaped form and the second plate-shaped form each have at least one slot adjoined by respective two fingers.

It is possible as well that the electronic control unit has three capacitors. According to this design, the first plate-shaped form and the second plate-shaped form have one slot, wherein each slot is adjoined by two respective fingers. The embodiment of the double insulation displacement connector (first plate-shaped form and parallel second plate-shaped form) have two fingers with one slot. Each insulation displacement connector is capable to receive two first or second electric lines from each of the two capacitors. The first or second electric lines are arranged in a line or may also have an offset.

In case the electronic control unit holds three capacitors, the first plate-shaped form and the second plate-shaped form have two slots, wherein each slot is adjoined by two fingers.

The insulation displacement connector having the first plate-shaped form parallel to the second plate-shaped form looks substantially the same as the insulation displacement connector having the single plate-shaped form. One plate-shaped form of the insulation displacement connector sits with an interference fit in the slot of the first or second tower. The first plate-shaped form and the second plate-shaped are connected by a thin bracket of U-shaped material.

According to the principle already mentioned, the slots of the first plate-shaped form and the second plate-shaped form, when inserted in the first tower, contact the first electric lines from the capacitors. Additionally, the slots of the first plate-shaped form and the second plate-shaped form, when inserted in the second tower, contact the second electric lines from the capacitors.

In an embodiment, at least one groove is formed in the first support, the second support and the third support of the first tower and the second tower to support and position the first and second electric lines from the capacitors. The grooves are aligned with each other. In case the electronic control unit holds two capacitors, the first plate-shaped form and the second plate-shaped form of each insulation displacement connector have one slot. The first support, the second support and the third support of the first tower and the second tower each have one single groove.

In case the electronic control unit holds three capacitors, the first plate-shaped form and the second plate-shaped form of each insulation displacement connector have two slots. The first support, the second support and the third support of the first tower and the second tower have two parallel grooves.

The designs of the insulation displacement connector according to the first or second design are suitable for reel packaging. More embodiments of the electronic control unit are possible by varying the way the capacitors are arranged relative to each other in the housing part. Additionally, more designs of the insulation displacement connector are possible, depending on the bending type of the first and second electric lines leads (90° bend, straight, S-bend).

The inventive embodiments of the electronic control unit have several advantages. According to the invention, the number of insulation displacement connectors is lowered from four to two insulation displacement connectors, if two capacitors are sharing the same insulation displacement connectors. In case three capacitors need to be connected with each other, the insulation displacement connectors each have three slots. Here as well, two insulation displacement connectors are used instead of six. In this way, assembly costs and the assembly time are reduced.

Additionally, according to the invention, the capacitor package in the housing part of the electronic control unit becomes more compact as some insulation displacement connectors and corresponding towers for insulation displacement connectors are eliminated. If the capacitor number determines the size of the electronic control unit, this means that the overall module dimension is reduces with the usage of same insulation displacement connectors for multiple capacitors.

A keep-out area of 3 mm for all types of components and 5 mm for sensitive components must be maintained around each connector (pin) of the insulation displacement connectors on both sides of the printed circuit board. If the number of insulation displacement connectors is reduced, there will be considerably more space on the printed circuit board for components layout. By reducing the size of the printed circuit board, the size of the electronic control unit can be further reduced.

Using the same mounting structures (cradles), capacitors, slightly modified connectors of the insulation displacement connector and towers for the insulation displacement connector, the same tools for bending and trimming of the first and second electric lines result in minimal changes to the overall architecture, which means easy implementation, minimal testing, low risks, increased confidence, etc.

### BRIEF DESCRIPTION OF THE DRAWINGS

The numerous advantages of the disclosure may be better understood by those skilled in the art by reference to the accompanying figures in which:

FIG. 1 shows a schematic representation of the placement of an embodiment of an electronic control unit (ECU) in a vehicle.

FIG. 2 is a perspective view of an embodiment of an ECU using insulation displacement connectors (IDCs) to electronically connect two capacitors that function as a back-up power supply.

FIG. 3 is a detailed side view of two IDCs positions in respective towers for the IDCs.

FIG. 4 is a detailed perspective view of an IDC used in relation with the present invention.

FIG. 5 is a detailed perspective view of an embodiment of a prior art IDC.

FIG. 6 is a perspective view of a further embodiment of an ECU in which the IDCs and the tower for the IDCs are designed to electronically connect two capacitors to function as a back-up power supply.

FIG. 7 is a top view of the arrangement of the IDCs (embodiment shown in FIGS. 8 and 9) in the respective IDC towers.

FIGS. 8 and 9 show perspective views of the IDC used in the embodiment of FIG. 6.

FIG. 10 is sectional top view showing the arrangement of the connectors to the capacitors in an IDC tower.

FIG. 11 is a detailed sectional view of two IDCs according to the embodiment of FIGS. 8 and 9 in respective towers for the IDCs.

FIG. 12 is a perspective view of IDC towers according to a prior art embodiment.

FIG. 13 is a perspective view of IDC towers for receiving the IDCs according to FIG. 5.

FIG. 14 is a perspective view of IDC towers for receiving the IDCs according to FIGS. 8 and 9.

### DETAILED DESCRIPTION

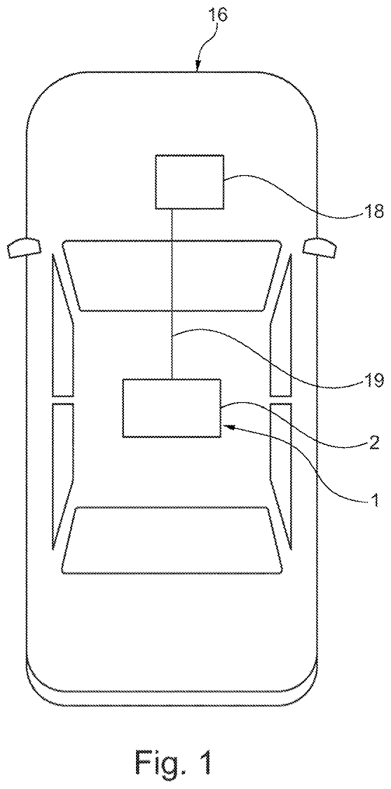

FIG. 1 shows a schematic representation of an embodiment of a placement of an electronic control unit (ECU) 1 for a vehicle 16. Electronic control unit 1 controls one or more electrical systems of vehicle 16 and is enclosed by a housing 2. Housing 2 may be made of plastics or metallic materials. In cases where vibrations are more extreme during use of vehicle 16, housing 2 may be made of metallic materials, such as die-cast aluminium. To provide electrical power to ECU 1, ECU 1 is electrically connected to a vehicle battery 18 (main battery), typically via an electric line 19. To ensure a permanent supply of electric power to the ECU 1 is connected with a back-up power unit, which is configured in the form of a capacitor. The relatively heavy capacitor must be mounted in the housing 2 of the ECU 1 to ensure back-up power supply in all traffic situations.

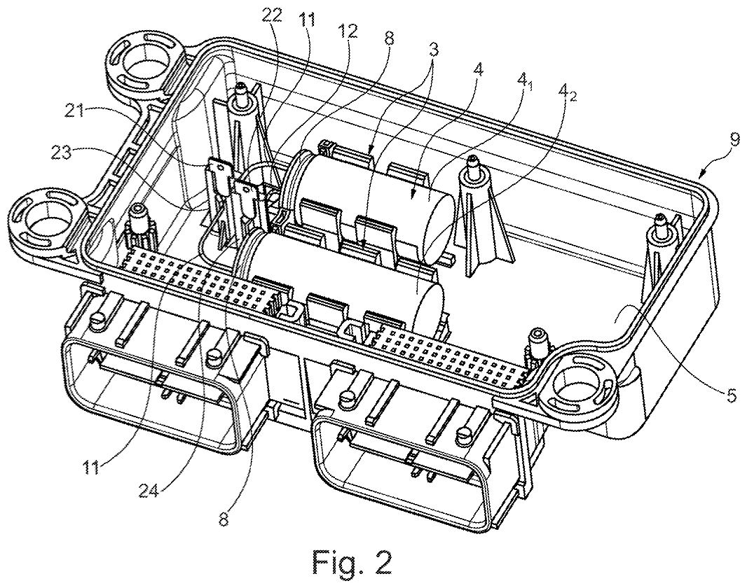

FIG. 2 shows a perspective view of an embodiment of a housing part 9 for a housing 2 of an ECU 1 (see FIG. 1) for accommodating at least a first capacitor 4₁ and a second capacitor 4₂. Bottom 5 of housing part 9 has a mounting structure 3 for each capacitor 4₁ and 4₂, which is an integral part of the housing part 9. Each capacitor 4₁ and 4₂, has a first electric line 11 and a second electric line 12. The first electric line 11 of each capacitor 4₁ and 4₂ is in electric contact with a first insulation displacement connector 21. The second electric line 12 of each capacitor 4₁ and 4₂ is in electric contact with a second insulation displacement connector 22. To achieve a stable and reliable electric connection of each capacitor 4₁ and 4₂ with the first insulation displacement connector 21 and the second insulation displacement connector 22, both of them are inserted into a first tower 23 and a second tower 24, respectively. The first tower 23 and the second tower 24 are as well integral parts of housing part 9.

In case housing part 9 is made of plastic, at least the mounting structures 3, the first tower 23 and the second tower 24 are formed as integral parts of bottom 5 of housing part 9 during the injection moulding process. Once capacitors 4₁ and 4₂ are positioned in mounting structure 3, a circumferential notch 8 of each of the capacitors 4₁ and 4₂ helps align the first electric line 11 and the second electric line 12 of capacitors 4₁ and 4₂ with respect to the first tower 23 and the second tower 24, respectively. Additionally, the circumferential notch 8 and the corresponding geometry of mounting structure 3 (cradle) have the role to prevent the accidental slip of the capacitors 4₁ and 4₂ out of the mounting structure 3 when drop tested along an axial direction of the of the capacitors 4₁ and 4₂.

For the purpose of the description, the embodiments described herein are limited to a first capacitor 4₁ and a second capacitor 4₂. It is obvious to those skilled in the art that housing part 9 may accommodate more than two capacitors as a back-up power supply 4.

FIG. 3 is a detailed view of the first tower 23 with an inserted first insulation displacement connector 21 and the second tower 24 with an inserted second insulation displacement connector 22. Second tower 24 is partially cut out to show the mounting of second insulation displacement connector 22 in second tower 24. In this embodiment, first insulation displacement connector 21 and second insulation displacement connector 22 have three fingers 30 and two slots 31. The slots 31 are formed between the three fingers 30.

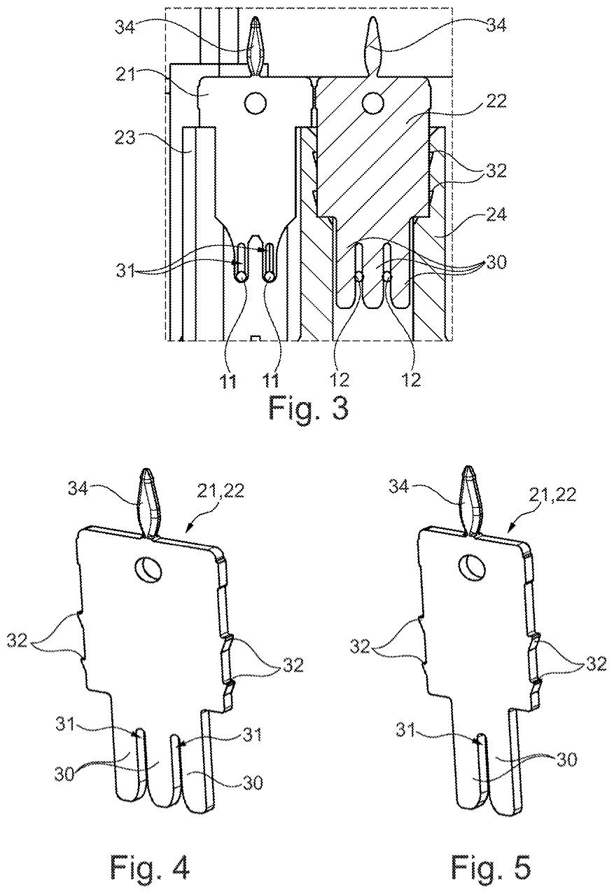

According to the embodiment shown in FIG. 4, insulation displacement connectors 21 and 22 each have three fingers 30 defining two (three minus one) slots 31. The slots 31 of first insulation displacement connector 21 are suitable for receiving the first electric lines 11 of first capacitor 4₁ and second capacitor 4₂. The slots 31 of second insulation displacement connector 22 are suitable for receiving the second electric lines 12 of first capacitor 4₁ and second capacitor 4₂. The first electric lines 11 the second electric lines 12 run in parallel in the region of the slots 31 of first insulation displacement connector 21 and second insulation displacement connector 22. It is obvious that the insulation displacement connectors 21 and 22 are not limited to three fingers 30 and two slots 31. The number of capacitors 4₁, 4₂, . . . , 4_{N} determines the number of slots 31 formed in the insulation displacement connectors 21 and 22. If the insulation displacement connectors 21 and 22 have a number L (greater than three) of fingers 30, the insulation displacement connectors 21 and 22 have L-1 slots 31.

A possible further embodiment, not shown, is that the first insulation displacement connector 21 and the second insulation displacement connector 22 each have four fingers 30 between which three (four minus one) slots 31 are formed. This embodiment allows the electric connection of three capacitors 4₁, 4₂ and 4₃ to first insulation displacement connector 21 and second insulation displacement connector 22 to form a back-up power supply with increased back-up power.

In FIG. 4, a perspective view of the first insulation displacement connector 21 or the second insulation displacement connector 22 according to an embodiment of the invention shows that the first insulation displacement connector 21 and the second insulation displacement connector 22 have barbed hooks 32. Each insulation displacement connector 21 or 22 is provided with a connector 34 to the printed circuit board (not shown) to deliver back-up power.

A prior art embodiment of the first insulation displacement connector 21 or the second insulation displacement connector 22 is shown in FIG. 5. This prior art embodiment has two fingers 30 in which one slot 31 is formed. Only a single electric line (not shown) can be connected to this prior art embodiment.

The barbed hooks 32 cooperate with the first tower 23 and the second tower 24 to ensure a secure and permanent fit of the first insulation displacement connector 21 and the second insulation displacement connector 22 in the first tower 23 and the second tower 24.

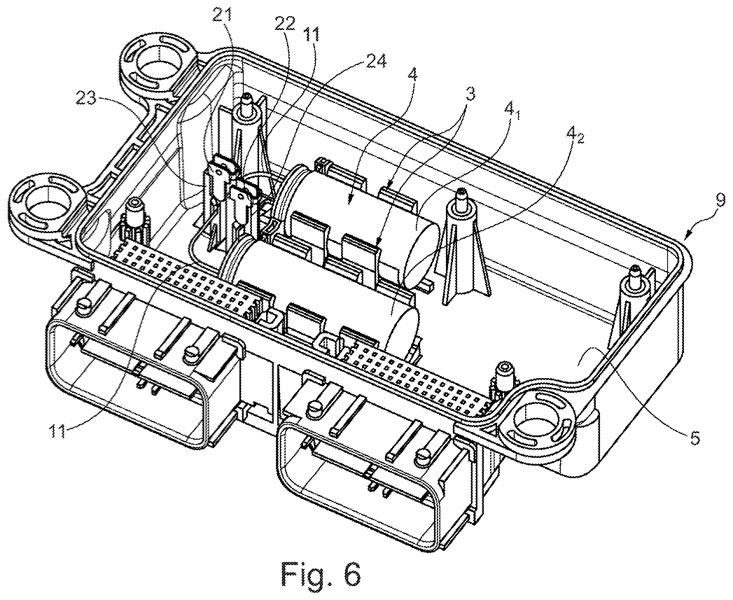

FIG. 6 shows a perspective view of a further embodiment of a housing part 9 for a housing 2 of an ECU 1 (see FIG. 1) for accommodating at least a first capacitor 4₁ and second capacitor 4₂. First capacitor 4₁ and second capacitor 4₂ are mounted to bottom 5 of housing part 9 by mounting structure 3. Each capacitor 4₁ and 4₂ has a first electric line 11 and a second electric line 12. The first electric line 11 of each capacitor 4₁ and 4₂ is in electric contact with the first insulation displacement connector 21 according to a further embodiment. The second electric line 12 of each capacitor 4₁ and 4₂ is in electric contact with the second insulation displacement connector 22 according to this embodiment. The mounting structure 3 for capacitors 4₁ and 4₂, the first tower 23 and the second tower 24 are integral parts of the bottom 5 of housing part 9.

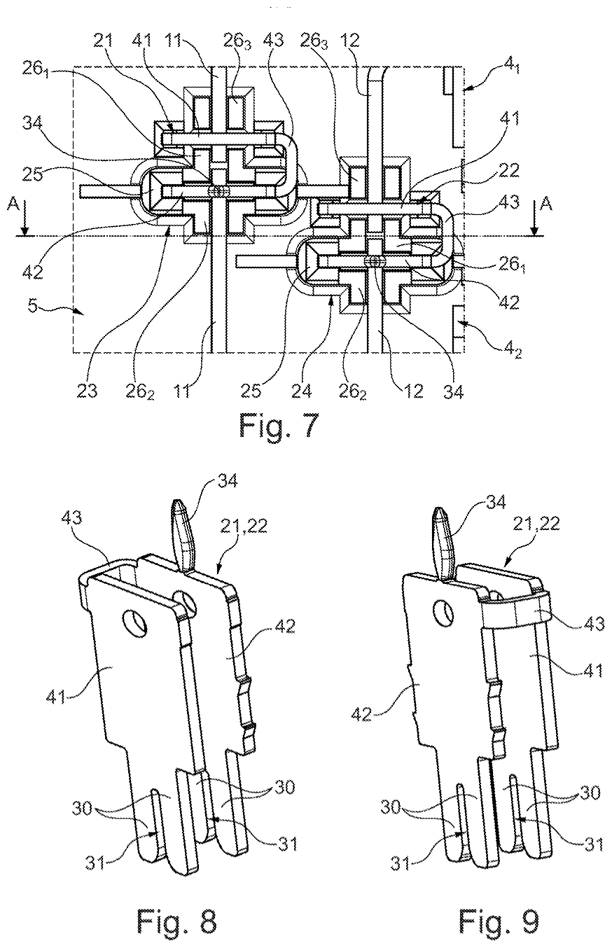

FIG. 7 shows a top view of a further embodiment of the first tower 23 and the second tower 24 on the bottom 5 of housing part 9. The first insulation displacement connector 21 and the second insulation displacement connector 22 are inserted into the first tower 23 and the second tower 24. The first electric lines 11 of the first capacitor 4₁ and the second capacitor 4₂ are colinearly arranged in the first tower 23 and are electrically contacted by the first plate-shaped form 41 and second plate-shaped form 42 of the first insulation displacement connector 21. The second electric lines 12 of the first capacitor 4₁ and the second capacitor 4₂ are colinearly arranged in the second tower 24 and are electrically contacted by the first plate-shaped form 41 and second plate-shaped form 42 of the second insulation displacement connector 22. The second plate-shaped form 42 of first insulation displacement connector 21 and second insulation displacement connector 22 has a connector 34 that provides an electric connection to a printed circuit board (not shown). The first insulation displacement connector 21 and the second insulation displacement connector 22 are mounted with its second plate-shaped form 42 in the slide 25 of the first tower 23 and the second tower 24 in a press-fit manner.

It is shown in the view of FIG. 7 that the first electric lines 11 and the second electric lines 12 from each capacitor are supported by the first support 26₁, the second support 26₂ or the third support 26₃. The embodiment of the first insulation displacement connector 21 and the second insulation displacement connector 22 connects, when inserted in the first tower 23 and the second tower 24, respectively, with its first plate-shaped form 41 and the second plate-shaped form 42 the first electric lines 11 or the second electric lines 12. The first electric lines 11 and the second electric lines 12 are supported on each side of the first plate-shaped form 41 and the second plate-shaped form 42 of the first insulation displacement connector 21 and the second insulation displacement connector 22. On each side of the first plate-shaped form 41, for example, the first electric line 11 form the first capacitor 4₁ is supported by the first support 26₁ and the third support 26₃. On each side of the second plate-shaped form 42, for example, the first electric line 11 form the second capacitor 4₂ is supported by the first support 26₁ and the second support 26₂. The first support 26₁, the second support 26₂ and the third support 26₃ are necessary in order to have the first electric line 11 and the second electric line 12 stand still when the first insulation displacement connector 21 and the second insulation displacement connector 22 are inserted.

The further embodiment of the first insulation displacement connector 21 and the second insulation displacement connector 22 is shown in FIGS. 8 and 9, wherein FIG. 9 shows the displacement connectors 21, 22 from the other side than FIG. 8. First insulation displacement connector 21 and second insulation displacement connector 22 each have a first plate-shaped form 41 and a second plate-shaped form 42 that are parallel to each other. First plate-shaped form 41 and second plate-shaped form 42 are each electrically connected to a bracket 43. Only second plate-shaped form 42 is provided with a connector 34, i.e. first plate-shaped form 41 is not provided with a connector 34. The first plate-shaped form 41 and the second plate-shaped form 42 each have at least one slot 31 which is adjoined by fingers 30.

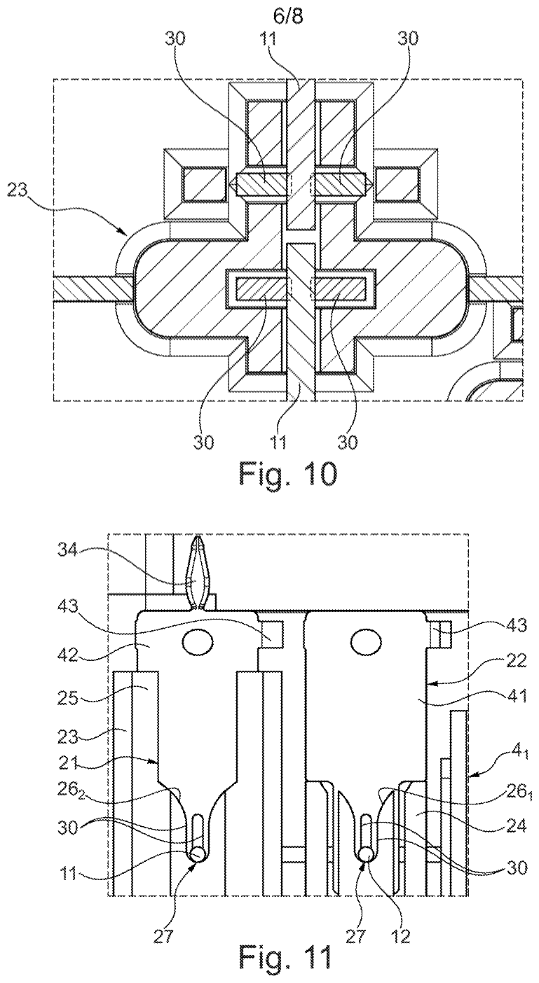

FIG. 10 shows a sectional view of the first tower 23 and the electric contacting of the first electric lines 11 by the first insulation displacement connector 21. Both electric lines 11 are colinearly arranged in the first tower 23. Once the first insulation displacement connector 21 is inserted in the first tower 23, the fingers 30 electrically contact the first electric lines 11 which enter the first tower 23 from opposite sides and are electrically separated from each other.

FIG. 11 shows a sectional view of the embodiments of first tower 23 and second tower 24 along line A-A of FIG. 7. Here, first tower 23 is provided with the inserted first insulation displacement connector 21. Second tower 24 is provided with an inserted second insulation displacement connector 22. According to this sectional view, second tower 24 is partially cut away to reveal first plate-shaped form 41 of second insulation displacement connector 22 positioned in second tower 24. Second plate-shaped form 42 of first insulation displacement connector 21 is inserted into a slide 25 of first tower 23. First electric line 11 of second capacitor 4₂ (not shown here) is placed on a groove 27 of a first support 26₁ and the second support 26₂ of first tower 23. The fingers 30 of second plate-shaped form 42 of first insulation displacement connector 21 contact the first electric line 11 of the second capacitor 4₂. The second electric line 12 of capacitor 4₁ is placed on a groove 27 of the first support 26₁ and a third support (not shown here) of second tower 24. The fingers 30 of first plate-shaped form 41 of second insulation displacement connector 22 contact the second electric line 12 of the first capacitor 4₁.

FIG. 12 shows a perspective view of a prior art embodiment of the first tower 23 and the second tower 24 for receiving the prior art first insulation displacement connector 21 and the prior art second insulation displacement connector 22 according to the prior art embodiment as shown in FIG. 5. The first tower 23 and the second tower 24 each have a slide 25 formed to receive the first insulation displacement connector 21 and the second insulation displacement connector 22, respectively. On one side of slide 25 of first tower 23 and second tower 24, a first support 26₁ is formed, and on the other side of slide 25, a second support 26₂ is formed. The first support 26₁ and the second support 26₂ each have a groove 27 formed to receive the first electric line 11 and the second electric line 12, respectively.

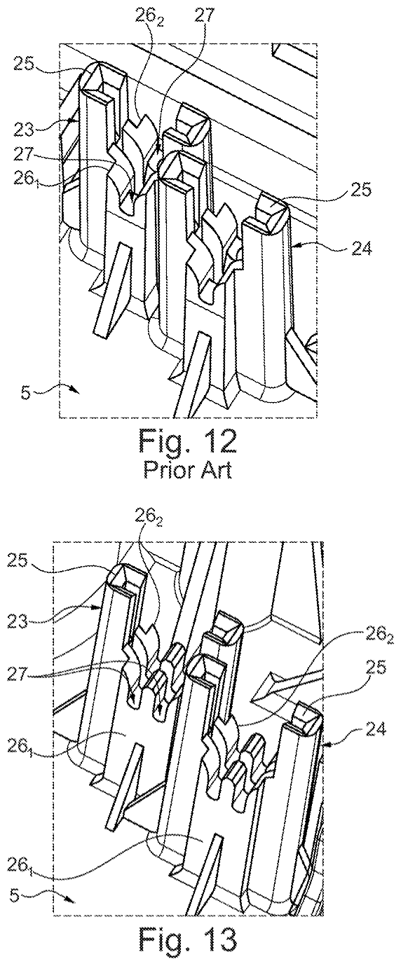

FIG. 13 shows a perspective view of an embodiment of the present invention. Here, the first tower 23 and the second tower 24 receive the first insulation displacement connector 21 and the second insulation displacement connector 22, respectively. The embodiment of the first insulation displacement connector 21 and the second insulation displacement connector 22 is shown in FIG. 4. The first tower 23 and the second tower 24 have a slide 25 formed to receive the first insulation displacement connector 21 and the second insulation displacement connector 22, respectively. A first support 26₁ is formed on one side of the slide 25 of the first tower 23 and the second tower 24, and a second support 26₂ is formed on the other side of the slide 25. According to the embodiment shown here, the first support 26₁ and the second support 26₂ each have two grooves 27 formed for receiving the first electric line 11 and the second electric line 12, respectively. As mentioned above, the number of grooves 27 should not be considered as a limitation of the invention. It is obvious to the person skilled in the art that the number of grooves 27 corresponds to the number of capacitors 4₁, 4₂, . . . , 4_{N} mounted on the bottom 5 of housing part 9.

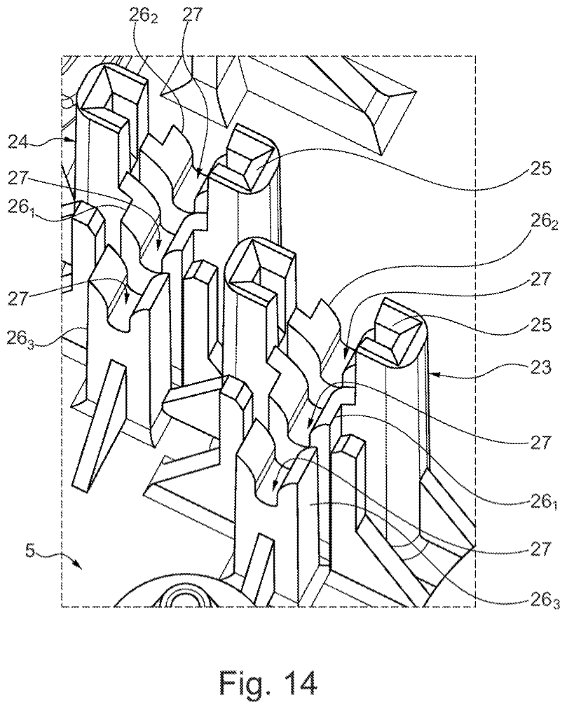

FIG. 14 shows a perspective view of a further embodiment of the first tower 23 and the second tower 24 for receiving the first insulation displacement connector 21 and the second insulation displacement connector 22 according to the embodiment shown in FIGS. 8 and 9. The first tower 23 and the second tower 24 each have a slide 25 formed to receive the second plate-shaped form 42 of the first insulation displacement connector 21 and the second insulation displacement connector 22, respectively. A first support 26₁ is formed on one side of the slide 25 of the first tower 23 and the second tower 24, and a second support 26₂ is formed on the other side of the slide 25 of the first tower 23 and the second tower 24. At least one single groove 27 is formed in the first support 26₁ and the second support 26₂, respectively. Additionally, a third support 26₃ is formed as a part of the first tower 23 and the second tower 24. The third support 26₃ is separate and spaced apart from the first support 26₁ of the first tower 23 and the second tower 24, respectively, to receive the first electric line 11 and the second electric line 12. In the embodiment shown here, one groove 27 is formed in the first support 26₁, the second support 26₂ and the third support 26₃ of the first tower 23 and the second tower 24. The grooves 27 of the first support 26₁, the second support 26₂ and the third support 26₃ are aligned. It is obvious to a person skilled in the art that the first support 26₁, the second support 26₂ and the third support 26₃ may each have more than one groove 27 that are aligned as well. In case more than two capacitors 4₁, 4₂, . . . 4_{N} are placed on the bottom 5 of housing part 9, the first support 26₁, the second support 26₂ and the third support 26₃ have more than one groove 27.

Returning to the embodiment shown in FIG. 14, the first electric line 11 from the capacitors 4₁, and 4₂ (see FIG. 6) are guided to the first tower 23. The second electric line 12 from the capacitors 4₁ and 4₂ (see FIG. 6) are guided to the second tower 24. The first electric line 11 of capacitor 4₁ enters the first tower 23 via the second support 26₃. The first electric line 11 of capacitor 4₂ enters the first tower 23 via the third support 26₂. The second electric line 12 of capacitor 4₁ enters the second tower 24 via the second support 26₃. The second electric line 12 of the capacitor 4₂ enters the second tower 24 via the third support 262.

### LIST OF REFERENCE NUMERALS

1 Electronic control unit (ECU)
2 Housing
3 Mounting structure, cradle
4 Back-up power supply
4₁, 4₂, . . . 4_{N} Capacitor
5 Bottom
8 Notch
9 Housing part
11 First electric line
12 Second electric line
16 Vehicle
18 Vehicle battery
19 Electric line
21 First insulation displacement connector
22 Second insulation displacement connector
23 First tower
24 Second tower
25 Slide
26₁ First support
26₂ Second support
26₃ Third support
27 Groove
30 Finger
31 Slot
32 Barbed hook
34 Connector
41 First plate-shaped form
42 Second plate-shaped form
43 Bracket
A-A Cut

1. An electronic control unit comprising
a back-up power supply defined by at least two capacitors, wherein the at least two capacitors are accommodated in a housing part of the electronic control unit, and each capacitor has a first electric line and a second electric line, and
a first insulation displacement connector positioned in a first tower and a second insulation displacement connector positioned in a second tower,
the first electric line of each capacitor being connected to the first insulation displacement connector, and the second electric line being connected to the second insulation displacement connector;
the first insulation displacement connector and the second insulation displacement connector each having a plurality of slots formed, the number of which corresponds to the number of capacitors forming the back-up power supply;
each of the slots of the first insulation displacement connector being adapted for receiving the first electric line of each capacitor, and
each of the slots of the second insulation displacement connector being adapted for receiving the second electric line of each capacitor.

2. The electronic control unit according to claim 1, wherein the first tower and the second tower each have a slide formed to receive the first insulation displacement connector and the second insulation displacement connector, respectively.

3. The electronic control unit according to claim 2, wherein a first support and a second support are provided on both sides of the slide of the first tower and the second tower.

4. The electronic control unit according to claim 3, wherein a plurality of grooves are formed in the first support and in the second support of the first tower for supporting the first electric line from the capacitors, and a plurality of grooves are formed in the first support and in the second support of the second tower for supporting the second electric line from the capacitors.

5. The electronic control unit according to claim 4, wherein the first insulation displacement connector and the second insulation displacement connector each have a plate-shaped form which fits into the slide of the first tower, thereby contacting, with the slots of the plate-shaped form, the first electric lines from the capacitors, and which fits into the slide of the second tower, thereby contacting, with the slots of the plate-shaped form, the second electric lines from the capacitors,
each of the slots of the first insulation displacement connector and the second insulation displacement connector being delimited by a pair of fingers.

6. The electronic control unit according to claim 1, wherein a third support is provided in separate relation to the first support of the first tower and the second tower.

7. The electronic control unit according to claim 6, wherein at least one groove is formed in the first support, the second support and the third support of the first tower for supporting the first electric lines from the capacitors, and at least one groove is formed in the first support, the second support and the third support of the second tower for supporting the second electric lines from the capacitors .

8. The electronic control unit according to claim 7, wherein the first insulation displacement connector and the second insulation displacement connector each are composed of a first plate-shaped form and a second plate-shaped form extending parallel to each other and being connected with a bracket, the first plate-shaped form and the second plate-shaped form each having at least one slot adjoined by respective two fingers.

9. The electronic control unit according to claim 8, wherein the second plate-shaped form fits into the slide of the first tower and the second tower, and the first plate-shaped form fits between the first support and the third support.

10. The electronic control unit according to claim 9, wherein the slots of the first plate-shaped form and the second plate-shaped form, inserted into the first tower, contact the first electric lines from the capacitors, and the slots of the first plate-shaped form and the second plate-shaped form, inserted in the second tower contact the second electric lines from the capacitors.

11. The electronic control unit according to claim 9, wherein the at least one groove of the first support, the second support and the third support of the first tower and the second tower are aligned with each other.

12. An electronic control unit comprising
a back-up power supply having N capacitors, N being an integer greater than or equal to 2, wherein the N capacitors are disposed in a housing of the electronic control unit, and each of the N capacitors has a first electric line and a second electric line, and
a first insulation displacement connector disposed in a first tower and a second insulation displacement connector disposed in a second tower,
the first electric line of each of the N capacitors being connected to the first insulation displacement connector, and the second electric line of each of the N capacitors being connected to the second insulation displacement connector;
the first insulation displacement connector and the second insulation displacement connector each having M slots, where M is an integer equal to N;
each of the M slots of the first insulation displacement connector configured to receive the first electric line of each capacitor; and
each of the M slots of the second insulation displacement connector configured to receive the second electric line of each capacitor.

13. The electronic control unit according to claim 12, wherein the first tower and the second tower each have a slide configured to receive the first insulation displacement connector and the second insulation displacement connector, respectively.

14. The electronic control unit according to claim 13, wherein a first support and a second support are provided on both sides of the slide of the first tower and the second tower.

15. The electronic control unit according to claim 14, wherein a first plurality of grooves are formed in the first support and in the second support of the first tower, the first plurality of grooves configured to support the first electric line from the capacitors, and a second plurality of grooves are formed in the first support and in the second support of the second tower, the second plurality of grooves configured to support the second electric line from the capacitors.

16. The electronic control unit according to claim 15, wherein the first insulation displacement connector and the second insulation displacement connector each have a plate-shaped form which fits into the slide of the first tower, thereby contacting, with the slots of the plate-shaped form, the first electric lines from the N capacitors, and which fits into the slide of the second tower, thereby contacting, with the slots of the plate-shaped form, the second electric lines from the N capacitors,
each of the slots of the first insulation displacement connector and the second insulation displacement connector being delimited by a pair of fingers.

17. The electronic control unit according to claim 12, wherein a third support is provided in separate relation to the first support of the first tower and the second tower.

18. The electronic control unit according to claim 17, wherein at least one groove is formed in the first support, the second support, and the third support of the first tower configured to support the first electric lines from the N capacitors, and at least one groove is formed in the first support, the second support, and the third support of the second tower configured to support the second electric lines from the N capacitors.

19. The electronic control unit according to claim 18, wherein the first insulation displacement connector and the second insulation displacement connector each include of a first plate-shaped form and a second plate-shaped form extending parallel to each other and being connected with a bracket, the first plate-shaped form and the second plate-shaped form each having at least one slot adjoined by respective two fingers.

20. The electronic control unit according to claim 19, wherein the second plate-shaped form fits into the slide of the first tower and the second tower, and the first plate-shaped form fits between the first support and the third support.
